(19) United States
(12) Patent Application Publication
(10) Pub. No.: US 2022/0107351 A1
(43) Pub. Date: Apr. 7, 2022

(54) APPARATUS AND METHOD FOR OPERATING ARC SUPPRESSION COIL

(71) Applicant: ENSTO OY, Porvoo (FI)

(72) Inventor: Jyrki PENTTONEN, Helsinki (FI)

(73) Assignee: ENSTO OY, Porvoo (FI)

(21) Appl. No.: 17/426,471

(22) PCT Filed: Jan. 31, 2020
(86) PCT No.: PCT/FI2020/050060

§ 371 Date: Jul. 28, 2021

(30) Foreign Application Priority Data
Feb. 4, 2019 (FI) 20195071

(51) Int. Cl. G01R 31/08; G01R 31/10; H02H 9/08

(52) U.S. Cl. CPC G01R 31/086; H02H 9/08; G01R 31/10

(57) ABSTRACT

An apparatus and a method for operating an arc suppression coil in an electric power network are disclosed. The arc suppression coil is operated off-resonance with respect to a normal state resonance point of the electric power network during normal operation of the electric power network. An indication for an occurrence of an earth fault in the electric power network is received and, in response to the indication, the arc suppression coil is tuned towards resonance with respect to the normal state resonance point, while the earth fault is present in the electric power network.

### FIELD

The present disclosure relates to operating an electric power network. In particular, the disclosure relates to operating an electric power network during an earth fault.

### BACKGROUND

Earth faults cause interruptions in the delivery of electricity over electric power networks. They may be caused, for example, by a tree fallen on a power line creating a direct physical connection from the line to earth.

There are various alternatives for grounding an electric power network. In resonant-earthed networks, and compensated networks in particular, arc suppression coils are used to compensate for capacitine earth fault currents. The coil produces inductive reactance which at least partially compensates for the capacitive reactance in the network so that when an earth fault occurs, the resulting fault current is smaller than it would be without the arc suppression coil.

### OBJECTIVE

An objective is to improve performance of the current systems utilizing arc suppression coils.

In particular, it is an objective to provide a way to reduce the probability of a power outage due to an earth fault.

### SUMMARY

The present disclosure involves operating an arc suppression coil, also known as a Petersen coil (ASC). The arc suppression coil is adapted to be operated in an electric power network, which may be a three-phase network. The electric power network comprises power lines, which may be subject to earth faults. During an earth fault, such as a phase-to-earth fault, a power line comes into electric contact with earth, i.e. to the ground of the electric power network. This may take place through a fault arc, formed at the location of the earth fault.

According to a first aspect, an apparatus, such as a controller, for operating an arc suppression coil in an electric power network is disclosed. The apparatus is adapted to operate the arc suppression coil off-resonance with respect to a normal state resonance point of the electric power network during normal operation of the electric power network, i.e. in the absence of an earth fault. Tuning of the arc suppression coil may be controlled by adjusting the impedance, e.g. the inductance, of the arc suppression coil. This impedance is the impedance of the arc suppression coil visible to the electric power network and it may substantially correspond to the total inductive reactance of the electric power network. Tuning can be performed by adjusting the inductance of a single reactive element producing the inductance of the arc suppression coil visible to the electric power network. This allows adjusting the total inductance of the electric power network without coupling or decoupling any separate inductances to the electric power network. Instead of such a discrete adjustment, the arc suppression coil can be adapted for substantially continuous adjustment of inductance. In the normal state resonance point of the electric power network, the inductance of the arc suppression coil corresponds to a first value with which the inductive reactance of the electric power network optimally compensates the capacitive reactance of the electric power network, when the electric power network is in normal operation. For perfect compensation, the magnitude of the capacitive reactance of the electric power network is equal to the magnitude of the inductive reactance of the electric power network for the operating frequency of the electric power network. In off-resonance, the inductance, of the arc suppression coil is larger or smaller than the first value. The former case corresponds to an overcompensated state and the latter case corresponds to an undercompensated state. Operating the arc suppression coil off-resonance during normal operation of the electric power network allows the zero-sequence voltage of the electric power network to be decreased, resulting in reduced losses in the electric power network. In specific, decreasing zero-sequence voltage results in decreasing current in the arc suppression coil, reducing losses in the arc suppression coil. As an additional effect, operating the arc suppression coil off-resonance allows maintaining a smaller neutral voltage for the electric power network reducing voltage stress in the insulation of the electric power network.

The apparatus is also adapted to receive an indication for an occurrence of an earth fault in the electric power network and, in response to the indication, tune the arc suppression coil towards resonance with respect to the normal state resonance point, while the earth fault is present in the electric power network. This corresponds to adjusting the inductance of the arc suppression coil towards the first value. In an overcompensated state, the inductance is decreased, whereas in the undercompensated state the inductance is increased. Tuning the arc suppression coil when the earth fault is present in the electric power network allows absolute minimization of the fault current. Decreasing the fault current, in turn, increases the probability for extinguishing a fault arc corresponding to the earth fault. To extinguish the fault arc, the apparatus may be adapted to switch into a tracking mode, in response to the indication. In the tracking mode, the apparatus is adapted to tune the arc suppression coil towards resonance with respect to the normal state resonance point and monitor, whether the earth fault in the electric power network has been removed. These may be performed automatically allowing a quick response to an earth fault, even in milliseconds. When the apparatus has received an indication that the earth fault has been removed, the apparatus may be adapted to return to operating the arc suppression coil off-resonance with respect to the normal state resonance point of the electric power network. The solution allows flexibly adjusting the operation of the arc suppression coil when the earth fault is present, in contrast to earlier implementations where the inductance of the arc suppression coil remains constant during in the presence of an earth fault. Moreover, while several previous solutions aim to increase fault current at fault inception, the present solution in contrast allows decreasing the fault current at the location of the earth fault, which may significantly improve the probability to extinguish the fault arc and remove the earth fault, without the need to trip any protective relays. This allows earth fault removal by autonomous operation of the apparatus.

In an embodiment, the apparatus is adapted to tune the arc suppression coil by adjusting the reluctance of the arc suppression coil. This allows conveniently operating the arc suppression coil towards and/or away from resonance even when the earth fault is present in the electric power network. In a further embodiment, the apparatus is adapted to adjust the reluctance of the arc suppression coil by adjusting the size of a virtual air gap of the arc suppression coil. This allows the reluctance to be adjusted quickly, e.g. even in less than 1-10 milliseconds. It is noted that the arc suppression coil may, additionally or alternatively, be operated into and/or out of resonance using, for example, an inverter, which may be adapted to feed reactive current into the arc suppression coil. In comparison to this, the reluctance adjustment as disclosed here, e.g. by adjusting a virtual air gap, has an additional effect in that it may be performed without generating additional harmonics which impede extinguishing the fault arc.

It is noted that other means for varying the impedance of the arc suppression coil can also be used for tuning the arc suppression coil, including stepwise variation of impedance and other means. For example, impedance of the arc suppression coil may be varied by the arc suppression coil having one or more variable impedance windings, which can be adapted for varying the zero sequence impedance of the electric power network. Such a variable impedance winding may be formed, for example, by a switched capacitor bank. The one or more variable inductance windings may comprise, for example, one or more capacitors adapted for adjusting the impedance of the arc suppression coil, or zero sequence impedance of the electric power network in particular.

In an embodiment, the apparatus is adapted to tune the arc suppression coil to resonance with respect to the normal state resonance point. This allows quickly decreasing the fault current to maximize the probability of extinguishing the fault arc.

In an embodiment, the apparatus is adapted to determine a fault state resonance point of the electric power network or a value indicative thereof, while the earth fault is present in the electric power network. When the fault state resonance point differs substantially from that of the normal state resonance point, this allows finding the optimal point for minimizing the fault current and thereby maximizing the probability of extinguishing the fault arc. The fault state resonance point may be determined, for example, by maximizing the zero sequence voltage of the electric power network and/or by minimizing the negative sequence current of the electric power network when the earth fault is present in the electric power network. The apparatus may be further adapted to tune the arc suppression coil to resonance with respect to the fault state resonance point. This allows minimizing the fault current, in particular the reactive fault current, when the earth fault state is present in the electric power network. As the determination of the fault state resonance point takes some time, the arc suppression coil may first be tuned to resonance with respect to the normal state resonance point. However, in some cases the arc suppression coil may also be tuned directly to resonance with respect to the fault state resonance point before it has first been tuned to resonance with the normal state resonance point. In a further embodiment, the apparatus is adapted to maintain the arc suppression coil in resonance with respect to the fault state resonance point using repeated redetermination of the fault state resonance point or a value indicative thereof, while the earth fault is present in the electric power network. This allows the fault state resonance point to be tracked so that the fault current may be minimized even when the fault state resonance point changes.

In an embodiment, the apparatus is adapted to tune the arc suppression coil away from resonance to trip one or more relays in the electric power network. This allows using the apparatus to ensure that the one or more relays, which may be configured to function independently, trip when desired. The one or more relays are protective relays, such as feeder relays, and they can be adapted to disconnect a power line when the power line is subject to an earth fault. Consequently, this allows also protecting the electric power network and its surroundings from damage due to a fault arc corresponding to the earth fault as the apparatus can be adapted to trip the one or more relays to extinguish the fault arc by disconnecting the one or more power line protected by the one or more relays. Typically, the one or more relays may be configured to function independently so that they trip when the current and/or voltage in the one or more power lines protected by the one or more relays satisfies certain conditions, which may comprise exceeding a threshold value, optionally conditional on the threshold value being exceeded for a threshold time as well. While such relays typically trip automatically upon the occurrence of an earth fault, it is possible with the apparatus in accordance with the present disclosure to first attempt to extinguish the fault arc corresponding to the earth fault and, if the attempt is unsuccessful, trip a protective relay to extinguish the fault arc. In particular, this may be flexibly performed by adjusting the reluctance of the arc suppression coil, e.g. by adjusting the size of a virtual air gap of the arc suppression coil. Specific requirements posed for operation of the relays may be also set by local regulations, and the flexibility provided by the disclosed control procedure allows the requirements to be followed even when the current visible to the relays is initially suppressed in an attempt to extinguish the fault arc.

By tripping the one or more relays by tuning the arc suppression coil, additional costly equipment such as an oil-immersed resistor with a switching element are not needed. Moreover, tuning the arc suppression coil allows ensuring that the one or more relays see enough current for tripping, thereby removing any need to include additional resistive components in the electric power network which, especially maintained constantly present, may significantly reduce any chances of extinguishing the fault arc during an earth fault.

In a further embodiment, the apparatus is adapted to determine a threshold time for tripping a relay and tune the arc suppression coil away from resonance after the threshold time from receiving the indication for the occurrence of the earth fault in the electric power network. This allows the exposure of the electric power network and its surroundings to the earth fault to be limited. The threshold time may be dependent on the magnitude of the fault current.

In an embodiment, operating the arc suppression coil off-resonance corresponds to operating the arc suppression coil in an undercompensated state during normal operation of the electric power network. In this case, the magnitude of the capacitive reactance is larger than the magnitude of the inductive reactance in the electric power network during normal operation.

In an embodiment, the apparatus is adapted to determine the normal state resonance point and/or a fault state resonance point of the electric power network, or one or more indications thereof, by maximizing the zero sequence voltage of the electric power network. This provides a reliable measure for the resonance point, which can be made readily available in many electric power networks and which may be flexibly used also during the presence of an earth fault. The apparatus may be specifically adapted to determine the zero sequence voltage or a value indicative thereof for determining the normal state resonance point and/or a fault state resonance point of the electric power network, or one or more indications thereof. In another embodiment, which may be used additionally or alternatively with the solution of the previous embodiment, the apparatus is adapted to determine the normal state resonance point and/or a fault state resonance point of the electric power network, or one or more indications thereof, by minimizing the negative sequence current of the electric power network. This allows minimizing the fault current quickly and it may also allow improving the accuracy for determining the resonance point. The apparatus may be specifically adapted to determine the negative sequence current or a value indicative thereof for determining the normal state resonance point and/or a fault state resonance point of the electric power network, or one or more indications thereof. Both of the above embodiments allow operating the arc suppression coil without separate configuration such as determining the total capacitance of the electric power network.

In an embodiment, the indication for an occurrence of an earth fault is determined based on an increase in a zero sequence voltage of the electric power network or an indication thereof. This provides a reliable measure for the resonance point, which can be made readily available in many electric power networks. In another embodiment, which may be used additionally or alternatively with the solution of the previous embodiment, the indication for an occurrence of an earth fault is determined based on an increase in a negative sequence current of the electric power network or an indication thereof. Especially in certain situations, this may allow notably improving the accuracy for determining the occurrence of the earth fault. Again, both of the above embodiments allow operating the arc suppression coil without separate configuration such as determining the total capacitance of the electric power network. Similarly, an indication for the disappearance of the earth fault can be determined based on a decrease in the zero sequence voltage and/or the negative sequence current. The apparatus may be adapted to determine the indication for the occurrence of the earth fault and/or the indication for the disappearance of the earth fault, for example by one or more measurements.

According to a second aspect, a method for operating an arc suppression coil in an electric power network is disclosed. The method comprises operating the arc suppression coil off-resonance with respect to a normal state resonance point of the electric power network during normal operation of the electric power network. Moreover, the method comprises receiving an indication for an occurrence of an earth fault in the electric power network and, in response to the indication, tuning the arc suppression coil towards resonance with respect to the normal state resonance point, while the earth fault is present in the electric power network. The method may involve utilizing the apparatus in accordance with the first aspect or any of its embodiments. Also, any or all procedures disclosed may be applied as part of the method even if the apparatus as such is not used.

In an embodiment, the arc suppression coil is tuned towards resonance by adjusting the reluctance of the arc suppression coil. In a further embodiment, the reluctance of the arc suppression coil is adjusted by adjusting the size of a virtual air gap of the arc suppression coil.

According to a third aspect, a computer program product comprises instructions which, when executed by a computer, cause the computer to carry out the method in accordance with the second aspect or any of its embodiments.

The normal state resonance point or a value indicative thereof is determined during normal operation of the electric power network, whereas the fault state resonance point or a value indicative thereof may be determined when an earth fault is present in the electric power network. The determination may be performed by the apparatus. The determination may be based on one or more measurements, which may be local, of current and/or voltage. The one or more measurements may comprise one or more measurements of phase current and/or phase voltage from a phased power line. The normal state resonance point and/or the fault state resonance point may be determined by maximizing the zero sequence voltage, for example by an iterative method, and/or by minimizing the fault current of the electric power network, for example by minimizing the negative sequence current of the electric power network. Alternatively or additionally, the normal state resonance point and/or the fault state resonance point may be determined by another method such as a current injection method.

As an example, for determination of the normal state resonance point and/or the fault state resonance point, one or more current measurements from the one or more relays may be used by using automation protocols such as DNP, IEC or Goose. A faulty feeder can be identified by comparing zero sequence voltage with one or more phase voltages. Once the faulty feeder has been identified, the arc suppression coil can be tuned so that negative sequence current, which may be measured directly from the one or more relays, gets minimized. Negative sequence current in a faulty feeder can be used as a good estimate of fault current at the fault location. Reading the current measurements directly from feeder protection relays thereby allows the negative sequence current in the faulty feeder to be used as an accurate approximation of the fault current at the fault location. Furthermore, reading measurement values from several, or even from all, feeders allows the measurement results to be compared with each other allowing further improvement in fault current estimation accuracy.

The zero sequence voltage may be determined as an average of phase voltages in the electric power network. This can be done also when there is no star point in the electric power network for measuring a physical zero voltage. In the absence of a neutral point in the electric power network, a phase voltage can be considered as the voltage between a phased power line and the earth of the electric power network. In a three-phase network, the zero sequence voltage may thus be determined as a sum of the three phase voltages of the electric power network, corresponding to different phases in the electric power network, divided by three. The determination may be performed by the apparatus. The determination may be based on one or more measurements, which may be local, of current and/or voltage. The one or more measurements may comprise one or more measurements of phase current and/or phase voltage from a phased power line.

An indication of change in the state of the electric power network may be used to allow an efficient control procedure for the electric power network. Such an indication of change in the state may be an indication of change in the zero sequence voltage of the electric power network and/or an indication of change in the fault current of the electric power network, for example an indication of change in the negative sequence current. The indication of change in the state of the electric power network alone can be used to control the operation of the arc suppression coil to detect an occurrence and/or a disappearance of an earth fault and, alternatively or additionally, to determine the normal state resonance point and/or a fault state resonance point of the electric power network. Consequently, the operation of the arc suppression coil can be controlled solely based on measurements indicative of change in the state of the electric power network, and no configuration measurements such as measurements for the total capacitance of the electric power network are required. The measurements indicative of change in the state of the electric power network may comprise measurements indicative of the zero sequence voltage and/or of the fault current, e.g. of the negative sequence current. The indication of change may be determined when necessary, for example by the apparatus. It may be determined, for example, for determining the normal state resonance point and/or a fault state resonance point of the electric power network. Any indications of change in the state of the electric power network may also be monitored, for example by the apparatus, e.g. by sustained or continuous monitoring.

In some electric power networks, such as symmetric networks, the zero sequence voltage of the electric power network may be low. There, an impedance element may be connected between one phase and the earth to increase the zero sequence voltage.

Alternatively or additionally to using the zero sequence voltage or a value indicative thereof, the arc suppression coil may be operated based on one or more measurements indicative of the fault current during the earth fault. One way to estimate the amount of the fault current at the location of the earth fault is to measure current in a substation transformer of the electric power network or in one or more power lines of the electric power network, e.g. in one or more power lines going out of a substation of the electric power network. In particular, the negative sequence current of the electric power network may be used as an estimate for the fault current. During an earth fault, the arc suppression coil can thereby be tuned based on the negative sequence current, for example by minimizing the negative sequence current to minimize the fault current. Using current measurements such as a measurement of the negative sequence current of the electric power network may allow notably improving the accuracy for operating the arc suppression coil. For example, for a low-impedance earth fault the negative sequence current may be used for providing a sharper resonance than many other methods allowing improved determination of the fault state resonance point of the electric power network.

The apparatus and method as disclosed herein may be adapted for autonomous operation. The arc suppression coil may be controlled independently based only on measurements indicative of the zero sequence voltage and/or the fault current, e.g. of the negative sequence current, which allows minimizing set-up and configuration tasks, enabling fast deployment. As the fault arc may be extinguished without tripping any protective relays, the earth fault can be made invisible to the end users of the electric power network and the occurrence of the fault does not necessarily necessitate any interruption in the delivery of electricity. This allows improvement on system average interruption frequency index and the system average interruption duration index for the electric power network.

It is to be understood that the aspects and embodiments described above may be used in any combination with each other. Several of the aspects and embodiments may be combined together to form a further embodiment.

### BRIEF DESCRIPTION OF THE DRAWINGS

The accompanying drawings, which are included to provide a further understanding and constitute a part of this specification, illustrate embodiments and together with the description help to explain the principles of the invention. In the drawings:

FIG. 1 illustrates an electric power network system according to an example,

FIG. 2 illustrates operating an arc suppression coil according to an example,

FIG. 3a illustrates a general arrangement for earth fault compensation,

FIG. 3b illustrates an arrangement for earth fault compensation according to an example,

FIG. 4 is a schematic diagram of a system for operating an arc suppression coil according to an example, and

FIGS. 5a,b illustrate operating an arc suppression coil according to an example.

Like references are used to designate equivalent or at least functionally equivalent parts in the accompanying drawings.

### DETAILED DESCRIPTION

The detailed description provided below in connection with the appended drawings is intended as a description of the embodiments and is not intended to represent the only forms in which the embodiment may be constructed or utilized. However, the same or equivalent functions and structures may be accomplished by different embodiments.

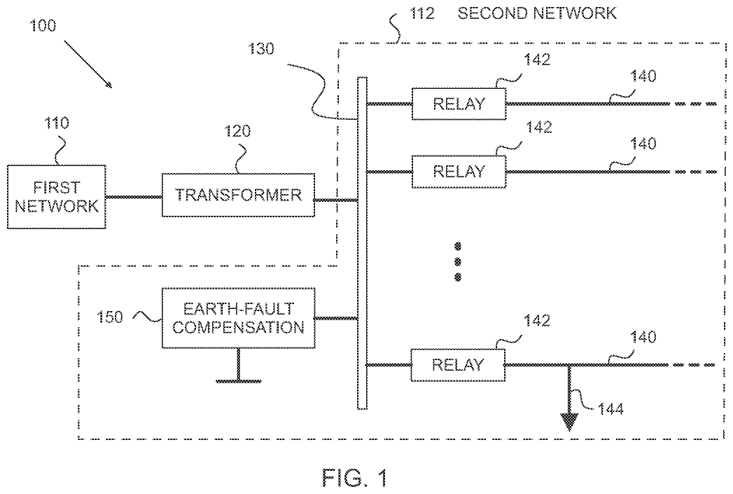

FIG. 1 shows an example of an electric power network system 100 (below also “the network system”). The network system 100 may be part of an electrical grid, e.g. a national or a regional grid, for delivering electricity from producers to consumers. The network system 100 may comprise a transmission network and/or a distribution network. The network system 100 may comprise a first network 110, such as a high-voltage network or a transmission network. In addition, the network system 100 may comprise a second network 112, such as a medium-voltage network, a distribution network or a low-voltage network. The network system 100 may further comprise a transformer 120, such as a substation primary transformer, for lowering the voltage from the first network 110 and/or to the second network 112. The second network 112 may be connected to the first network region 110 through the transformer 120.

In the following, earth-fault compensation is illustrated in the second network 112 (below also “the network”). However, it should be understood that the present invention may be used wherever an arc suppression coil, or a Petersen coil, is used.

The network 112 may be an alternating current network, such as a three-phase network. The network 112 may have an operating frequency, e.g. 50-60 Hz, which may be constant. The network 112 comprises an arrangement 150 (below also “the arrangement”) which may be adapted for earth fault compensation in the network 112, so that the network 112 is a compensated network. The arrangement 150 may be adapted to be located at an electrical substation, such as at the substation between a transmission network and a distribution network. However, the arrangement 150 may also be adapted to be located together with a distribution transformer, in which case the arrangement 150 may be adapted for distributed earth fault compensation. Consequently, the arrangement 150 may be used, for example, not only where high-voltage is converted to medium-voltage but, alternatively or additionally, where medium-voltage is converted to low-voltage. The arrangement 150 comprises one or more arc suppression coils, adapted to compensate capacitive reactance of the network 112 during an earth fault. The inductive reactance of the one or more arc suppression coils may substantially correspond to the inductive reactance of the network 112 so that the inductive reactance of the network 112 is substantially due to the one or more arc suppression coils. The arrangement 150 may be directly connected to earth, i.e. to the ground of the network 112. The arrangement 150 may, at least partially, comprise an apparatus, such as a controller, for operating the one or more arc suppression coils. However, it is noted that the apparatus may also be comprised in a distributed system for controlling the electric power network 112.

The electric power network 112 may comprise one or more feeders 140, e.g. distribution network feeders, for feeding electricity forward in the network 112. A feeder 140 may be an overhead feeder or an underground feeder. A feeder 140 may comprise one or more power lines. For example, in a three-phase network a feeder 140 may comprise three power lines, one for each phase. A feeder 140 may be protected by one or more relays 142, i.e. protective relays, which may adapted to disconnect the one or more power lines of the feeder 140 during a fault, such as an earth fault. Consequently, the fault current corresponding to an earth fault may be removed by tripping one or more of the one or more relays 142. The one or more relays 142 may be adapted for independent operation, for example in that they measure current and/or voltage in one or more power lines of the feeder 140 and disconnect the one or more power lines under specified conditions. These measurements may be local, i.e. at the feeder 140. A relay 142 can be adapted to disconnect one or more power lines, e.g. by opening its own breaker, if it finds a fault condition. The one or more relays 142 may comprise a microprocessor. While the relays 142 may be adapted for various types of fault situations, it is noted that in typical networks the functioning and reliability of the relays 142 may be affected by their operating conditions.

The electric power network 112 may comprise a bus 130 such as a substation bus. The bus 130 may be a medium-voltage bus. The bus 130 may be arranged to connect the arrangement 150 to the one or more feeders 140. Alternatively or additionally, the bus 130 may be arranged to connect the arrangement 150 to the transformer 120. The arrangement 150 may be used to provide earth fault compensation to a plurality of feeders 140.

An earth fault may take place when a power line of a feeder 140 comes into electric contact with the earth. In principle, a fault location 144 may be at any point along the length of the feeder 140, which may have a length of several kilometers.

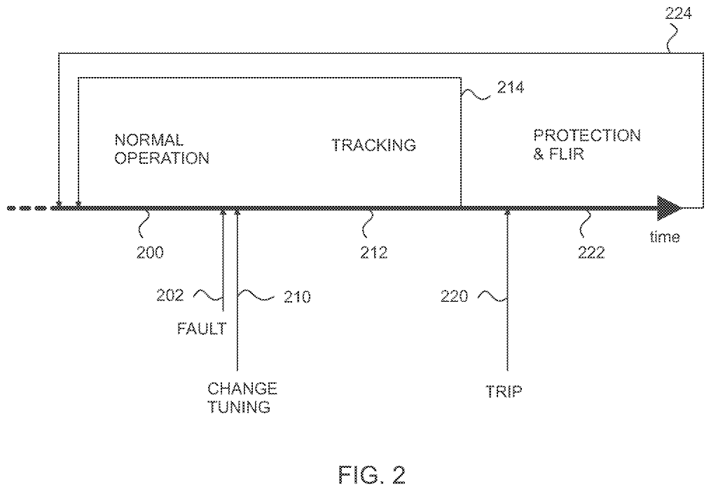

FIG. 2 shows an example of operating an arc suppression coil. The operation of the arc suppression coil may be controlled by the apparatus for operating an arc suppression coil. In normal operation 200, the arc suppression coil is operated off-resonance with respect to a normal state resonance point of the network 112. This means that the inductance of the arc suppression coil is adjusted so that the magnitude of the inductive reactance of the network 112 differs from the magnitude of the capacitive reactance of the network 112. The arc suppression coil may be operated off-resonance by 5-20 percent, when calculated from the total capacitance of the network 112, e.g. from the line-to-earth capacitance. However, the present disclosure allows even larger values, for example up to 50-70 percent. Increasing the departure from resonance allows reducing the zero sequence voltage of the network 112, which may in turn reduce power losses in the network 112.

Normal operation 200 of the network 112 is interrupted by the occurrence of an earth fault 202 in the network 112. As a result, a fault current will flow at the fault location 144 between the faulty feeder 140 and the earth. Since the arc suppression coil is operated off-resonance, the fault current, which may be over 10 A, e.g. 15-20 A, has both a resistive component and a reactive component, the latter of which may be for example 7-15 A. In response to the earth fault, an indication is received, e.g. by the apparatus, for the occurrence of the earth fault. The occurrence may be determined, for example, based on an increase in a zero sequence voltage of the network 112 or an indication thereof and/or an increase in the negative sequence current of the network 112 or an indication thereof. This determination may be based on one or more measurements of current and/or voltage. The measurements may be local, e.g. at a bus 130 such as a substation bus directly connected to the arrangement 150 for earth fault compensation.

When the indication for the occurrence of the earth fault has been received, the tuning of the arc suppression coil is changed 210, e.g. by the apparatus. Importantly, the tuning is changed while the earth fault is present in the network 112. Tuning the arc suppression coil towards resonance reduces the reactive component of the fault current, thereby reducing the total fault current. This may markedly improve the probability of extinguishing the fault arc, thereby removing the earth fault. Moreover, it allows reducing the risk of damage from dangerously high contact voltage. The arc suppression coil may be tuned directly or sequentially to resonance with respect to the normal state resonance point in an attempt to remove the earth fault. Alternatively or additionally, it is possible to determine a fault state resonance point of the network 112 or a value indicative thereof, while the earth fault is present in the network 112, and tune the arc suppression coil to resonance with respect to this fault state resonance point. This may allow even further reduction in the fault current, when the fault state resonance point has shifted substantially from the normal state resonance point. In typical real-world networks, the fault state resonance point remains close or substantially at the normal state resonance point. This means that any initial change in tuning towards the normal state resonance point corresponds also to a change in tuning towards the fault state resonance point. An initial change in tuning towards the fault state resonance point, which equals a change in tuning towards the normal state resonance point, can therefore be made already before the fault state resonance point or a value indicative thereof has been determined. This allows quick reaction to the occurrence of the earth fault as the tuning may be changed in milliseconds or even less. Naturally, the determination for the fault state resonance point may also be performed before any change in tuning.

The change in tuning can be considered as entering into a tracking mode 212 for attempting to extinguish the fault arc. In the tracking mode 212, after an initial change in tuning the tuning may be maintained constant or it may be changed, for example by repeated redetermination of the fault state resonance point or a value indicative thereof, which may be performed automatically. The repeated redetermination allows the fault current to be minimized even when the fault state resonance point changes. The change in tuning can be adapted to directly minimize the fault current, by tuning the arc suppression coil into resonance, but the change in tuning may also be performed sequentially. It has been found out that, in many practical situations, lowering the fault current below 10 A has an elevated probability of extinguishing the fault arc. Consequently, tuning the arc suppression coil towards resonance when the earth fault is present, has been found to have a practically viable chance for extinguishing the fault arc and thus removing the earth fault, without interrupting the delivery of electricity. If the attempt to extinguish the fault arc is successful, the arc suppression coil may be returned 214 to off-resonance for normal operation 200 of the network 112. The disappearance of the earth fault may be determined based on a decrease in the zero sequence voltage of the network 112 or an indication thereof and/or on a decrease in the negative sequence current of the network 112 or an indication thereof.

If, after one or more changes in tuning of the arc suppression coil, the attempt to extinguish the fault arc has not been successful, the arc suppression coil may be tuned away from resonance to trip 220 the one or more relays 142 in the network 112 to disconnect one or more power lines in the feeder 140 where the earth fault is present. This allows the network 112 and its surroundings to be protected as the fault current can be removed, thereby extinguishing also the fault arc. The tripping may be performed after a threshold time has passed from the occurrence of the earth fault 202, or the receipt of an indication thereof. The threshold time may be as small as, for example, 100-1000 milliseconds but it can also be larger, if appropriate. In particular, the threshold time may be dependent on the magnitude of the fault current so that for small enough levels of fault current it may be even infinite. While such a threshold time may be configured in the relays 142, the suppression of the fault current during the tracking mode means that the relays 142 may not necessarily have the correct information regarding the conditions of the earth fault, such as the actual time of occurrence of the earth fault. However, changing the tuning of the arc suppression coil allows flexibly triggering one or more relays 142 even when they are configured to function independently. The threshold time may also be determined based on one or more regulations pertaining to operation of the network 112, allowing flexible compliance with different regulatory regimes.

Once one or more relays 142 have been tripped, fault location, isolation and removal (FLIR) operations may be performed 222 to remove the earth fault. Once the earth fault has been removed, the arc suppression coil may be returned 224 to off-resonance for normal operation 200 of the network 112.

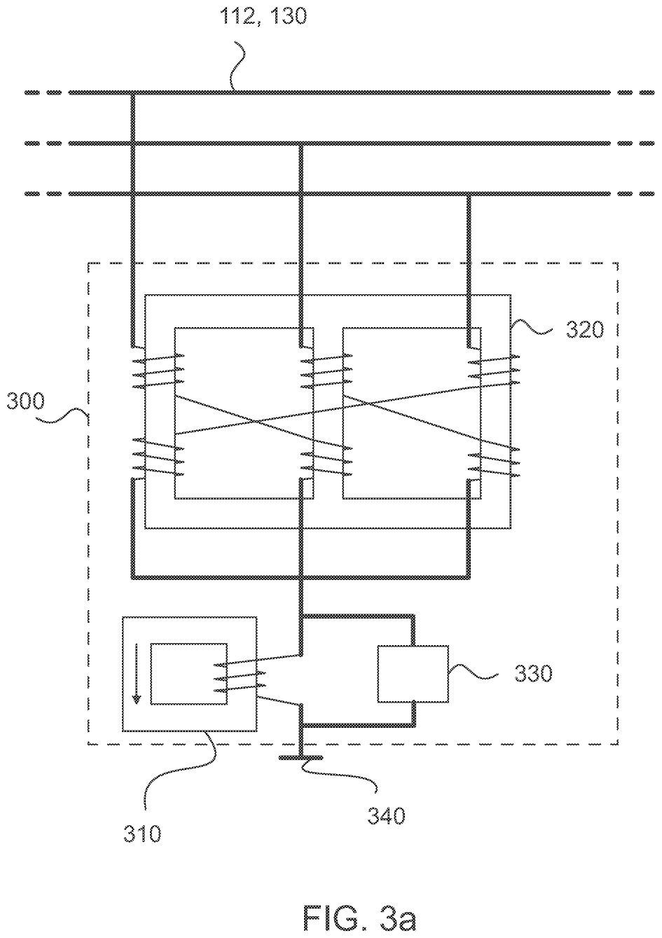

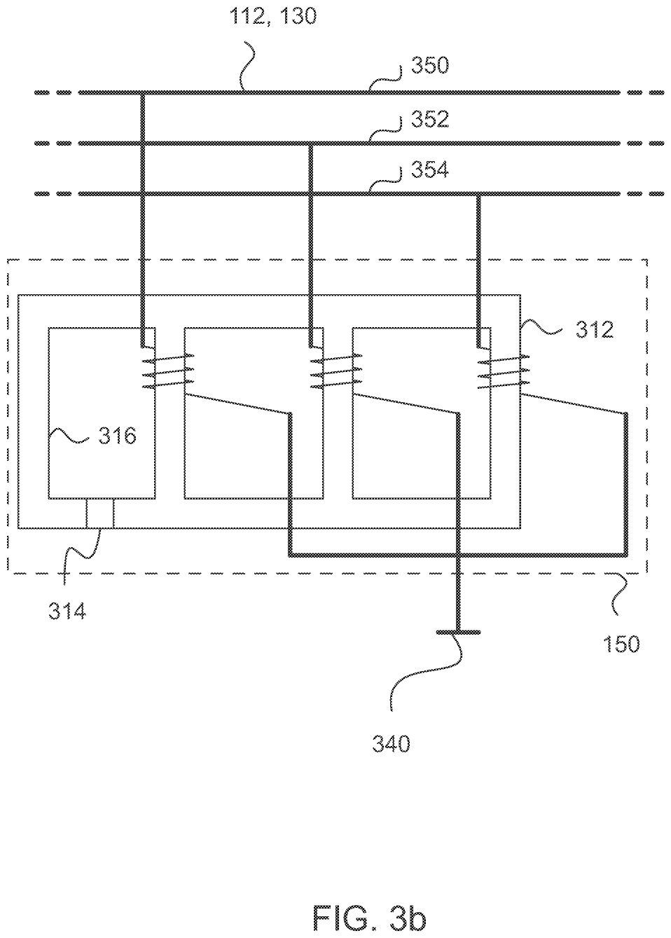

FIG. 3a illustrates a general arrangement 300 for earth fault compensation. The arc suppression coil is operated in the network 112, which can be a three-phase network. The general arrangement 300 comprises an arc suppression coil 310 adapted to compensate earth faults in the network 112. In addition, the general arrangement 300 comprises an earthing transformer 320 through which the arc suppression coil 320 is connected to other parts of the network 112, e.g. through the bus 130. The general arrangement 300 is grounded to the earth 340 and the grounding connection may be made directly from the arc suppression coil 310, which is typically mechanically operated, for example so that a motor inside a transformer moves a metallic component, and cannot be adjusted during an earth fault. Consequently, a general arrangement 300 often comprises means 330 such as an oil-immersed high-power resistor together with a switch, which may be used during an earth fault to connect the resistor in parallel with the arc suppression coil 310. The arrangement 150 of the present disclosure may be formed in accordance with the general arrangement 300 but with the arc suppression coil being adapted for its inductance to be adjustable during the presence of an earth fault.

FIG. 3b illustrates an arrangement 150 for earth fault compensation according to an example. While the present disclosure may be used also with a regular arc suppression coil 310, such as the one disclosed above, together with means such as inverter, this particle example is illustrated as it allows particularly flexible operation of the arc suppression coil when an earth fault is present in the network 112.

In the example, the arc suppression coil 312 is operated in the network 112, which can be a three-phase network. The arrangement 150 comprises an arc suppression coil 312 adapted to compensate earth faults in the network 112. Importantly, the arc suppression coil 312 is adapted for its inductance to be adjusted while an earth fault is present in the network 112. It is therefore enough to use a single arc suppression coil 312 having an adjustable inductance but naturally the arrangement may also comprise one or more additional arc suppression coils. The arc suppression coil 312 may even be formed as one monolithic structure functioning both as an earthing transformer and an inductive compensator for the capacitive reactance of the network 112.

The inductance may be adjusted by adjusting the reluctance of the arc suppression coil 312, for example by adjusting the size of a virtual air gap 314 of the arc suppression coil. No separate earthing transformers and/or parallel resistors are needed, which may allow reduction in both cost and size of the arrangement 150. The inductance may be adjusted electrically, allowing notable increase in speed in comparison to mechanical adjustment means.

The arc suppression coil 320 may be directly connected to other parts of the network 112, for example directly to the bus 130. The arrangement 150 is grounded to the earth 340 and the grounding connection may be made directly from the arc suppression coil 312. In the absence of the earthing transformer, the arrangement 150 can be made without a star point, at least as a physical point. Correspondingly, the star point of the arrangement 150 may be a virtual star point. The zero sequence voltage for the network 112 or a value indicative thereof may be determined by calculation, e.g. as an average of measured phase voltages 350, 352, 354. The arrangement 150 can be made with substantially negligible DC (direct current) resistance.

The arrangement 150 may comprise means, such as an actuator, for forming a virtual air gap 314 in the arc suppression 312 for adjusting the reluctance of the arc suppression coil 312. The arc suppression coil 312 may be adapted to form a virtual air gap 314, for example at a limb and/or a yoke of the arc suppression coil 312. One example for forming a virtual air gap 314 is given as follows. A virtual air gap 314 may be formed electrically, for example by at least one winding wound at the arc suppression coil 312 in a transformer core of the arc suppression coil 312. The winding may be wound at a transformer core of the arc suppression coil 312, for example partially or fully around a limb 316 and/or a yoke of the arc suppression coil 312, e.g. through the limb 316 and/or the yoke. For the purpose of forming the virtual air gap 314, the arc suppression coil 312 may comprise a separate path for zero sequence magnetic flux, for example in form of a loop.

The magnitude of the virtual air gap 314 may be adapted to be controlled by feeding current, for example DC current, into the winding. The winding(s) may be adapted to locally saturate the magnetic core of the path, when fed with the current, creating an effect similar to an air gap in the path and thereby increasing the reluctance of the path. The winding(s) may be arranged so that there is no induction to the winding circuit from the AC (alternating current) windings of the arc suppression coil 312 or the arrangement 150 connected to the phased power lines of the network 112. The virtual air gap 314 allows substantially linear operation of the arc suppression coil 312. It also allows very fast tuning, e.g. adjusting inductance of the arc suppression coil between a high and a low value in milliseconds. With electrical control of the reluctance of the arc suppression coil 312, no motors and/or moving parts are required, which may allow the size, cost and maintenance requirements of the arrangement 150 to be reduced.

The arc suppression coil 312 may be formed as a conventional arc suppression coil 310 with adjustable reluctance and used together with a separate earthing transformer. However, as stated above, the arc suppression coil 312 may also be formed as one monolithic structure functioning both as an earthing transformer and an inductive compensator for the capacitive reactance of the network 112. The arc suppression coil 312 may, for example, comprise a three-phase reactor for grounding the network 112 having three limbs and the separate path for zero sequence magnetic flux may be formed between the opposing ends of the three limbs of the three phase reactor, for example through a fourth limb. In an example, the arc suppression coil 312 comprises four or more limbs 316, where the arc suppression coil 312 is adapted for a path for zero sequence flux to be created through one of the limbs. The arc suppression coil 312 comprises means for forming a virtual air gap 314 for adjusting the reluctance of the path. The three other limbs comprise windings and connections for the three phases of a three-phase network 112. The path is formed as a return path for flux between the opposite ends of the three limbs. The design of the arc suppression coil 312 may correspond to that of a traditional reactor. The path with the virtual air gap 314 provides one example which allows capturing a part of the leakage flux of an arc suppression coil 312 for controlling the inductance of the arc suppression coil 312.

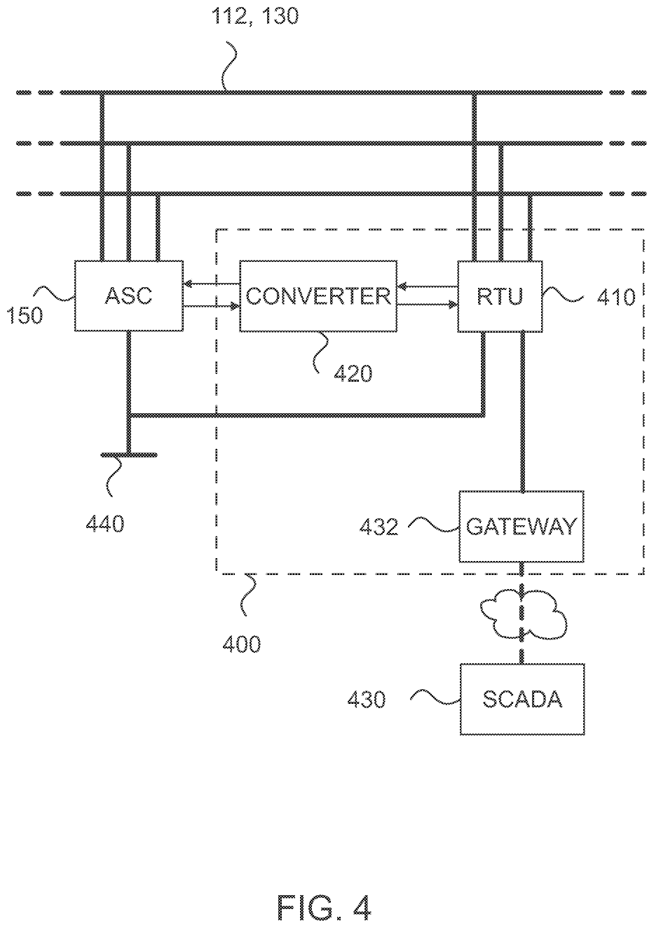

FIG. 4 is a schematic diagram of a system 400 for operating an arc suppression coil according to an example. The system 400 is adapted to be electrically connected to the arrangement 150 for earth fault compensation. Moreover, the system 400 is adapted to be electrically connected to the network 112, for example to the bus 130. The network 112 may be, for example, delta-connected. The system 400 may be a local system, for example at an electrical substation or at a distribution transformer.

The system 400 comprises an apparatus 410, such as a controller, for operating an arc suppression coil. The apparatus 410 may be adapted to function as a stand-alone unit but for many typical applications, the apparatus 410 can be adapted to function as a part of a distributed system 430 for controlling the network 112, e.g. it may be a remote terminal unit (RTU), such as an RTU of a SCADA system. The apparatus 410 may be adapted to be connected to the network 112, e.g. to the bus 130, for determining information indicative of the status of the network 112, e.g. a normal state and/or fault state resonance point of the network 112.

The apparatus 410 may comprise at least one processor and at least one memory comprising computer program code. The at least one memory and the computer program code can be configured to, with the at least one processor, operate the arc suppression coil of the arrangement 150 off-resonance with respect to a normal state resonance point of the network 112 during normal operation of the network 112, receive an indication for an occurrence of an earth fault in the network 112 and, in response to the indication, tune the arc suppression coil towards resonance with respect to the normal state resonance point, while the earth fault is present in the network 112. The at least one memory and the computer program code can be further configured to, with the at least one processor, perform any or all of the functions disclosed herein for operating the arc suppression coil and/or determining information indicative of the state of the network 112 such as the zero sequence voltage of the network 112 and/or the negative sequence current of the network 112.

The apparatus 410 is electrically connected to the arc suppression coil for operating the arc suppression coil, in particular for adjusting the inductance of the arc suppression coil. Specifically, while the apparatus 410 is adapted to adjust the inductance of the arc suppression coil during normal operation of the network 112, the apparatus 410 may be adapted to adjust the inductance of the arc suppression coil also while the earth fault is present in the network 112. This means that the arc suppression coil can be tuned with respect to the resonance point of the network 112 both in the absence and presence of an earth fault. For tuning the arc suppression coil, the apparatus 410 may be adapted to control one or more analog outputs (V_{COMP}) for controlling the inductance of the arc suppression coil, for example by feeding current, such as DC current, to the one or more windings adapted for forming a virtual air gap 314 for adjusting the reluctance of the arc suppression coil. Voltage- and/or current-based control may be used. The system 400 may comprise a converter 420, e.g. a DC-DC converter or an AC-DC converter, between the arc suppression coil and the apparatus 410. The converter 420 may have, for example, an analog input of 0-10 V from the apparatus 410 and/or a current output of 0-30 A to the arrangement 150. The apparatus 410 may be grounded to an earth 440, which may be the earth 340 of the arrangement 150 for earth fault compensation, for example by a direct connection.

The apparatus 410 may be arranged to function independently for operating an arc suppression coil. For this purpose, it may use one or more measurements indicative of zero sequence voltage of the network 112 and/or one or more measurements indicative of negative sequence current voltage of the network 112. Alternatively or additionally, other types of measurements may be used. The one or more measurements may be local measurements. The one or more measurements may be performed at the bus 130, e.g. at a substation bus. The apparatus 410 may be adapted to function without separate configuration with respect to the network 112. For example, it does not need to know the magnitude of the capacitance of the network 112. It is enough to use the one or more measurements indicative of the zero sequence voltage and/or the negative sequence current of the network to operate the arc suppression coil. The zero sequence voltage may be maximized, for example, by dithering.

The system 400 may comprise a gateway 432 for remote communication with one or more external systems, e.g. with a distributed system 430 such as a SCADA system. The apparatus 410 may be adapted to be connected to the one or more external systems 430 through the gateway 432. For example, the gateway 432 may conform to the standard IEC 61850 and/or IEC 60870, such as IEC 60870-5-104.

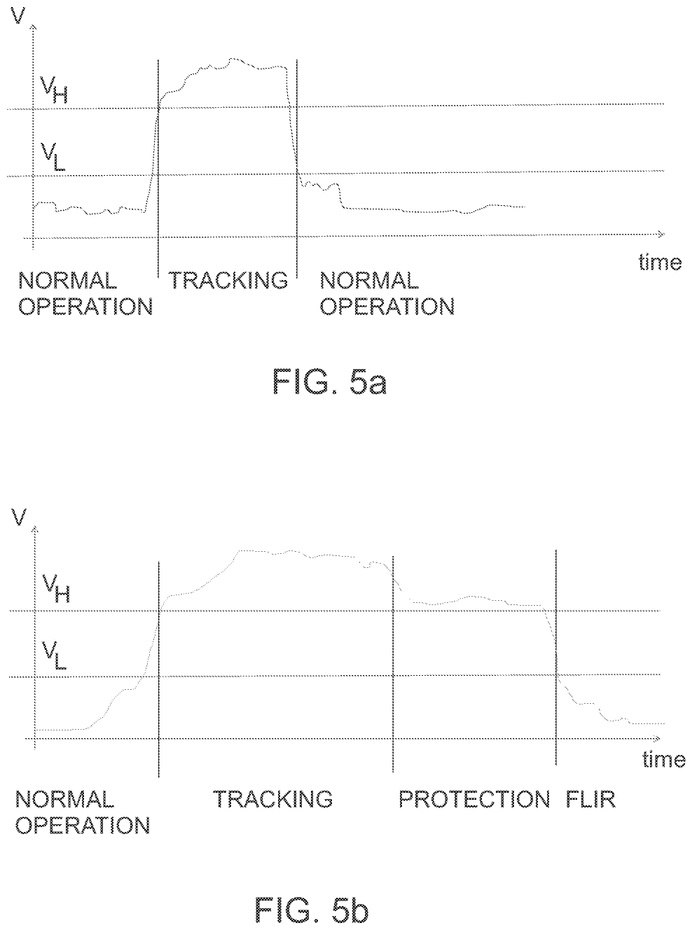

FIGS. 5a,b illustrate operating an arc suppression coil according to an example. In the figures and in the text below, an example development of the zero sequence voltage V of the network 112 is illustrated as a function of time. It should be understood that additionally or alternatively to any determination indicative of a voltage, such as the zero sequence voltage of the network, another determination, such as a determination indicative of the fault current in the network e.g. a determination indicative of the negative sequence current of the network, may be used. A threshold for voltage may thereby be replaced by a threshold for current.

During normal operation of the network 112 the zero sequence voltage remains below a first threshold voltage V_{H}. The occurrence of an earth fault can be determined based on an increase of the zero sequence voltage above the first threshold voltage V_{H}. In response, the arc suppression coil may be tuned in one or more attempts to try to remove the earth fault. This corresponds to initiating a tracking mode for attempting to remove the earth fault.

If the attempt is successful, a case illustrated in FIG. 5a, the zero sequence voltage decreases. The disappearance of the earth fault can be determined based on a decrease of the zero sequence voltage below a second threshold voltage V_{L}. Once it has been determined that the earth fault has disappeared, the arc suppression coil can be returned to off-resonance for normal operation of the network 112.

If the attempt is not successful, a case illustrated in FIG. 5b, the zero sequence voltage remains at an elevated level. In this case, the arc suppression coil may be tuned away from resonance to trip one or more relays for protecting the network 112 and its surroundings. This corresponds to initiating a protection mode for removing current from the faulty feeder. The finite time required for a relay to react has been illustrated in the figure but it should be noted that this is not necessarily in scale and the actual reaction time may be small. Once the current has been removed, the zero sequence voltage decreases. The removal of the fault current can be determined, for example, based on a decrease of the zero sequence voltage below the second threshold voltage V_{L}. Once it has been determined that the fault current has disappeared, fault location, isolation and removal operations may be performed for the network 112.

It is noted that a first threshold value, such as the first threshold voltage V_{H} or a first threshold current, may be used for determining the occurrence of an earth fault. Also, a second threshold value, such as a second threshold voltage V_{L} or a second threshold current, may be used for determining the disappearance of an earth fault. The first threshold value and/or the second threshold value may be compared, for example by the apparatus 410, to the zero sequence voltage of the network or a value indicative thereof and/or to the negative sequence current of the network or a value indicative thereof. The apparatus 410 may be adapted to bring about measurement of the zero sequence voltage or a value indicative thereof and/or of the negative sequence current of the network or a value indicative thereof, for example from the bus 130. The first threshold value and the second threshold value may be the same but they can also be different, for example so that the first threshold value corresponds to a larger zero sequence voltage than the second threshold value. This can be used to reduce the occurrence of false positives and/or negatives for determination of the presence of the earth fault.

The apparatus may be implemented in software, hardware, application logic or a combination of software, hardware and application logic. The application logic, software or instruction set may be maintained on any one of various conventional computer-readable media. A “computer-readable medium” may be any media or means that can contain, store, communicate, propagate or transport the instructions for use by or in connection with an instruction execution system, apparatus, or device, such as a computer. A computer-readable medium may comprise a computer-readable storage medium that may be any media or means that can contain or store the instructions for use by or in connection with an instruction execution system, apparatus, or device, such as a computer. The exemplary embodiments can store information relating to various processes described herein. This information can be stored in one or more memories, such as a hard disk, optical disk, magneto-optical disk, RAM, and the like. One or more databases can store the information used to implement the exemplary embodiments of the present inventions. The databases can be organized using data structures (e.g., records, tables, arrays, fields, graphs, trees, lists, and the like) included in one or more memories or storage devices listed herein. The databases may be located on one or more devices comprising local and/or remote devices such as servers. The processes described with respect to the exemplary embodiments can include appropriate data structures for storing data collected and/or generated by the processes of the devices and subsystems of the exemplary embodiments in one or more databases.

All or a portion of the exemplary embodiments can be implemented using one or more general purpose processors, microprocessors, digital signal processors, micro-controllers, and the like, programmed according to the teachings of the exemplary embodiments, as will be appreciated by those skilled in the computer and/or software art(s). Appropriate software can be readily prepared by programmers of ordinary skill based on the teachings of the exemplary embodiments, as will be appreciated by those skilled in the software art. In addition, the exemplary embodiments can be implemented by the preparation of application-specific integrated circuits or by interconnecting an appropriate network of conventional component circuits, as will be appreciated by those skilled in the electrical art(s). Thus, the exemplary embodiments are not limited to any specific combination of hardware and/or software.

The different functions discussed herein may be performed in a different order and/or concurrently with each other.

Any range or device value given herein may be extended or altered without losing the effect sought, unless indicated otherwise. Also any embodiment may be combined with another embodiment unless explicitly disallowed.

Although the subject matter has been described in language specific to structural features and/or acts, it is to be understood that the subject matter defined in the appended claims is not necessarily limited to the specific features or acts described above. Rather, the specific features and acts described above are disclosed as examples of implementing the claims and other equivalent features and acts are intended to be within the scope of the claims.

It will be understood that the benefits and advantages described above may relate to one embodiment or may relate to several embodiments. The embodiments are not limited to those that solve any or all of the stated problems or those that have any or all of the stated benefits and advantages. It will further be understood that reference to ‘an’ item may refer to one or more of those items.

The term ‘comprising’ is used herein to mean including the method, blocks or elements identified, but that such blocks or elements do not comprise an exclusive list and a method or apparatus may contain additional blocks or elements.

It will be understood that the above description is given by way of example only and that various modifications may be made by those skilled in the art. The above specification, examples and data provide a complete description of the structure and use of exemplary embodiments. Although various embodiments have been described above with a certain degree of particularity, or with reference to one or more individual embodiments, those skilled in the art could make numerous alterations to the disclosed embodiments without departing from the spirit or scope of this specification.

1. An apparatus for operating an arc suppression coil in an electric power network, wherein the apparatus being adapted to:
operate the arc suppression coil off-resonance with respect to a normal state resonance point of the electric power network during normal operation of the electric power network;
receive an indication for an occurrence of an earth fault in the electric power network; and
in response to the indication, tune the arc suppression coil towards resonance with respect to the normal state resonance point, while the earth fault is present in the electric power network.

2. The apparatus according to claim 1, adapted to tune the arc suppression coil by adjusting the reluctance of the arc suppression coil.

3. The apparatus according to claim 2, adapted to adjust the reluctance of the arc suppression coil by adjusting the size of a virtual air gap of the arc suppression coil.

4. The apparatus according to claim 1, adapted to tune the arc suppression coil to resonance with respect to the normal state resonance point.

5. The apparatus according to claim 1, adapted to determine a fault state resonance point of the electric power network or a value indicative thereof, while the earth fault is present in the electric power network, and tune the arc suppression coil to resonance with respect to the fault state resonance point.

6. The apparatus according to claim 5, adapted to maintain the arc suppression coil in resonance with respect to the fault state resonance point using repeated redetermination of the fault state resonance point or a value indicative thereof, while the earth fault is present in the electric power network.

7. The apparatus according to claim 1, adapted to tune the arc suppression coil away from resonance to trip one or more protective relays in the electric power network.

8. The apparatus according to claim 7, adapted to determine a threshold time for tripping a relay and tune the arc suppression coil away from resonance after the threshold time from receiving the indication for the occurrence of the earth fault in the electric power network.

9. The apparatus according to claim 1, wherein operating the arc suppression coil off-resonance corresponds to operating the arc suppression coil in an undercompensated state.

10. The apparatus according to claim 1, adapted to determine the normal state resonance point and/or a fault state resonance point of the electric power network, or one or more indications thereof, by maximizing the zero sequence voltage of the electric power network and/or minimizing the negative sequence current of the electric power network.

11. The apparatus according to claim 1, wherein the indication for an occurrence of an earth fault is determined based on an increase in a zero sequence voltage of the electric power network or an indication thereof and/or on an increase in the negative sequence current of the electric power network or an indication thereof.

12. A method for operating an arc suppression coil in an electric power network, wherein the method comprising:
operating the arc suppression coil off-resonance with respect to a normal state resonance point of the electric power network during normal operation of the electric power network;
receiving an indication for an occurrence of an earth fault in the electric power network; and
in response to the indication, tuning the arc suppression coil towards resonance with respect to the normal state resonance point, while the earth fault is present in the electric power network.

13. The method according to claim 12, wherein the arc suppression coil is tuned by adjusting the reluctance of the arc suppression coil.

14. The method according to claim 13, wherein the reluctance of the arc suppression coil is adjusted by adjusting the size of a virtual air gap of the arc suppression coil.

15. A computer program product comprising instructions which, when executed by a computer, cause the computer to carry out the method of claim 12.
